(19) United States
(12) Patent Application Publication
(10) Pub. No.: US 2026/0236131 A1
(43) Pub. Date: Aug. 13, 2026

(54) ELECTRONIC DEVICE

(71) Applicant: Samsung Electronics Co., Ltd., Suwon-si (KR)

(72) Inventors: Sunjun JANG, Suwon-si (KR); Sungkyo SEO, Suwon-si (KR); Sangbum YOUM, Suwon-si (KR); Jongmin JEONG, Suwon-si (KR)

(21) Appl. No.: 19/633,263

(22) Filed: Mar. 30, 2026

Related U.S. Application Data
(63) Continuation of application No. PCT/KR2024/096304, filed on Oct. 10, 2024.

(30) Foreign Application Priority Data
Oct. 11, 2023 (KR) 10-2023-0135348
Oct. 31, 2023 (KR) 10-2023-0148191

(51) Int. Cl. G06F 3/046; G06F 3/041; H05K 5/00; H05K 9/00; G06F 3/0354

(52) U.S. Cl. CPC G06F 3/046; G06F 3/04164; H05K 5/0018; H05K 9/0083; G06F 3/03545; G06F 2203/04107

(57) ABSTRACT

The disclosure relates to an electronic device. An electronic device is provided. The electronic device includes a display panel, an electronic module disposed around the display panel, a processor configured to control the electronic module, and a digitizer disposed beneath the display panel, wherein the digitizer includes a first conductive layer on which a plurality of first coils are disposed, a second conductive layer on which a plurality of second coils are disposed, wherein the first conductive layer is disposed between the second conductive layer and the display panel, and a signal line disposed in at least one of the first conductive layer and the second conductive layer, the signal line electrically connecting the processor to the electronic module.

### CROSS-REFERENCE TO RELATED APPLICATIONS

This application is a continuation application, claiming priority under 35 U.S.C. § 365(c), of an International application No. PCT/KR2024/096304, filed on Oct. 10, 2024, which is based on and claims the benefit of a Korean patent application number 10-2023-0135348, filed on Oct. 11, 2023, in the Ministry of Intellectual Property (MOIP), and of a Korean patent application number 10-2023-0148191, filed on Oct. 31, 2023, in the Ministry of Intellectual Property (MOIP), the disclosure of each of which is incorporated by reference herein in its entirety.

### BACKGROUND

### 1. Field

The disclosure relates to an electronic device, e.g., an electronic device including a digitizer.

### 2. Description of Related Art

With the remarkable advancement of information and communication technology and semiconductor technology, the distribution and use of various electronic devices are rapidly increasing. In particular, recent electronic devices are being developed to be portable and capable of communication.

An electronic device may refer to a device that performs a specific function according to a mounted program, such as home appliances, electronic organizers, portable multimedia players, mobile communication terminals, tablet personal computers (PCs), video/audio devices, desktop/laptop computers, or vehicle navigation systems. For example, such electronic devices may output stored information as sound or video.

As the integration density of electronic devices increases and ultra-high-speed, high-capacity wireless communication becomes common, recently, various functions may be mounted on a single electronic device such as a mobile communication terminal. For example, not only a communication function but also an entertainment function such as a game, a multimedia function such as music/video playback, a communication and security function such as mobile banking, and a schedule management or electronic wallet function are being integrated into a single electronic device. These electronic devices have been downsized to be conveniently carried by users.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide an electronic device, e.g., an electronic device including a digitizer.

Additional aspects will be set forth in part in the description which follows and, in part, will be apparent from the description, or may be learned by practice of the presented embodiments.

In accordance with an aspect of the disclosure, an electronic device is provided. The electronic device includes a display panel, an electronic module disposed around the display panel, a processor configured to control the electronic module, and a digitizer disposed beneath the display panel, wherein the digitizer includes a first conductive layer on which a plurality of first coils are disposed, a second conductive layer on which a plurality of second coils are disposed, wherein the first conductive layer is disposed between the second conductive layer and the display panel, and a signal line disposed in at least one of the first conductive layer and the second conductive layer, the signal line electrically connecting the electronic module and the processor. According to an embodiment, by replacing a wire (e.g., a cable, a flexible printed circuit (FPC), or the like) connected to the electronic module with the signal line inside the digitizer, the number of components of the electronic device is minimized.

In accordance with another aspect of the disclosure, an electronic device is provided. The electronic device includes a display panel, an electronic module disposed around an edge of the display panel, a processor configured to control the electronic module, and a digitizer disposed beneath the display panel. The digitizer includes a first conductive layer on which a plurality of first coils are disposed, a second conductive layer on which a plurality of second coils are disposed, the second conductive layer being disposed between the first conductive layer and the display panel, a shielding layer disposed beneath the first conductive layer, and a ground layer disposed beneath the shielding layer, the ground layer including a connecting portion connected to the first conductive layer through an outer edge of the shielding layer. According to an embodiment, the line inside the digitizer is effectively grounded.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating an electronic device in a network environment according to an embodiment of the disclosure;

FIG. 2 is an exploded perspective view illustrating a front side of an electronic device according to an embodiment of the disclosure;

FIG. 3 illustrates an input module and a digitizer according to an embodiment of the disclosure;

FIG. 4 is a cross-sectional view illustrating a digitizer according to an embodiment of the disclosure;

FIGS. 5 and 6 illustrate a portion of a digitizer and an electronic module according to various embodiments of the disclosure;

FIG. 7 is an enlarged view illustrating a portion of FIG. 6 according to an embodiment of the disclosure;

FIG. 8 is a cross-sectional view illustrating a digitizer according to an embodiment of the disclosure;

FIG. 9 illustrates a portion of an electronic device and a plurality of electronic modules according to an embodiment of the disclosure;

FIG. 10 is an enlarged view illustrating a portion of FIG. 9 according to an embodiment of the disclosure;

FIG. 11 is a cross-sectional view illustrating a digitizer according to an embodiment of the disclosure;

FIG. 12 is a view illustrating a state in which a second display area of a display is received in a housing according to an embodiment of the disclosure;

FIG. 13 is a view illustrating a state in which a second display area of a display is exposed to the outside of a housing according to an embodiment of the disclosure;

FIG. 14 is an exploded perspective view illustrating an electronic device according to an embodiment of the disclosure; and

FIG. 15 is a perspective view illustrating a portion of an electronic device and a digitizer according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It should be understood that the singular forms "a," "an," and "the" include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth^{®} chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

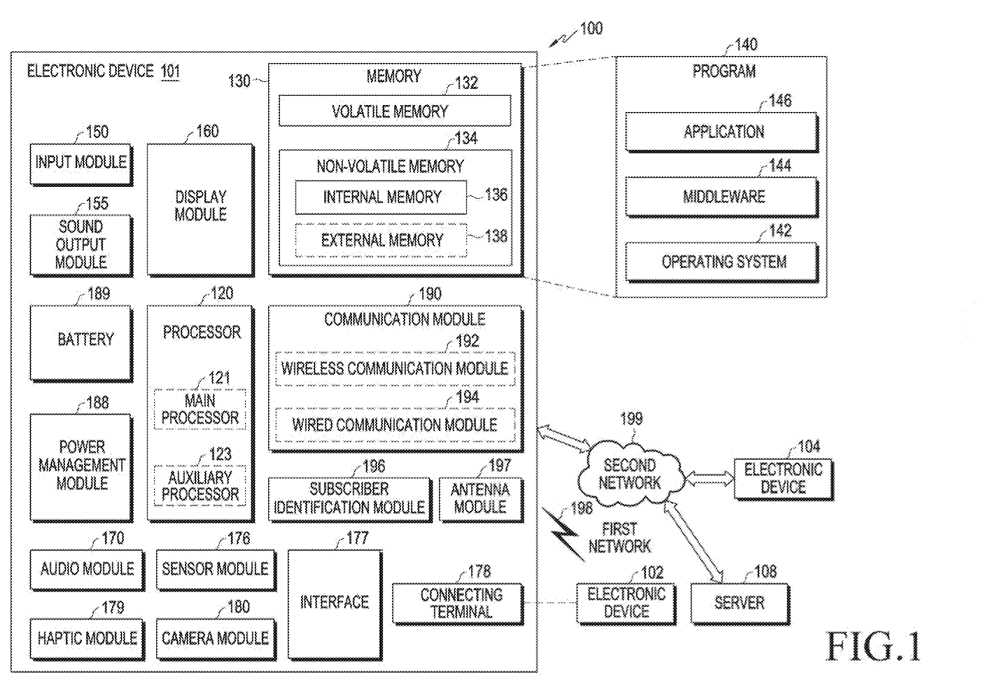

FIG. 1 is a block diagram illustrating an electronic device 101 in a network environment 100, according to an embodiment of the disclosure.

Referring to FIG. 1, the electronic device 101 in the network environment 100 may communicate with at least one of an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may execute, for example, software (e.g., the program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operation state (e.g., power or temperature) of the electronic device 101 or an external environmental state (e.g., the user's state), and then generate an electrical signal or data value corresponding to the detected state. According to an embodiment, the sensor module 176 may include, for example, a gesture sensor, a gyro sensor, an atmospheric pressure sensor, a magnetic sensor, an accelerometer, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wiredly) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wiredly) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth^{TM}, wireless-fidelity (Wi-Fi) direct, or infrared data association (IrDA)) or a second network 199 (e.g., a long-range communication network, such as a legacy cellular network, a fifth generation (5G) network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20Gbps or more) for implementing eMBB, loss coverage (e.g., 164dB or less) for implementing mMTC, or U-plane latency (e.g., 0.5ms or less for each of downlink (DL) and uplink (UL), or a round trip of 1ms or less) for implementing URLLC.

The antenna module 197 may transmit or receive a signal or power to or from the outside (e.g., the external electronic device). According to an embodiment, the antenna module 197 may include one antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, instructions or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or server 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments of the disclosure may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. As used herein, each of such phrases as "A or B," "at least one of A and B," “at least one of A or B,” "A, B, or C," "at least one of A, B, and C," and “at least one of A, B, or C,” may include all possible combinations of the items enumerated together in a corresponding one of the phrases. As used herein, such terms as "1st" and "2nd," or “first” and "second" may be used to simply distinguish a corresponding component from another, and does not limit the components in other aspect (e.g., importance or order). It is to be understood that if an element (e.g., a first element) is referred to, with or without the term “operatively” or “communicatively,” as “coupled with,” "coupled to," "connected with," or “connected to” another element (e.g., a second element), it means that the element may be coupled with the other element directly (e.g., wiredly), wirelessly, or via a third element.

As used herein, the term "module" may include a unit implemented in hardware, software, or firmware, and may interchangeably be used with other terms, for example, "logic," "logic block," "part," or "circuitry." A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The storage medium readable by the machine may be provided in the form of a non-transitory storage medium. Wherein, the term "non-transitory" simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store^{TM}), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. Some of the plurality of entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

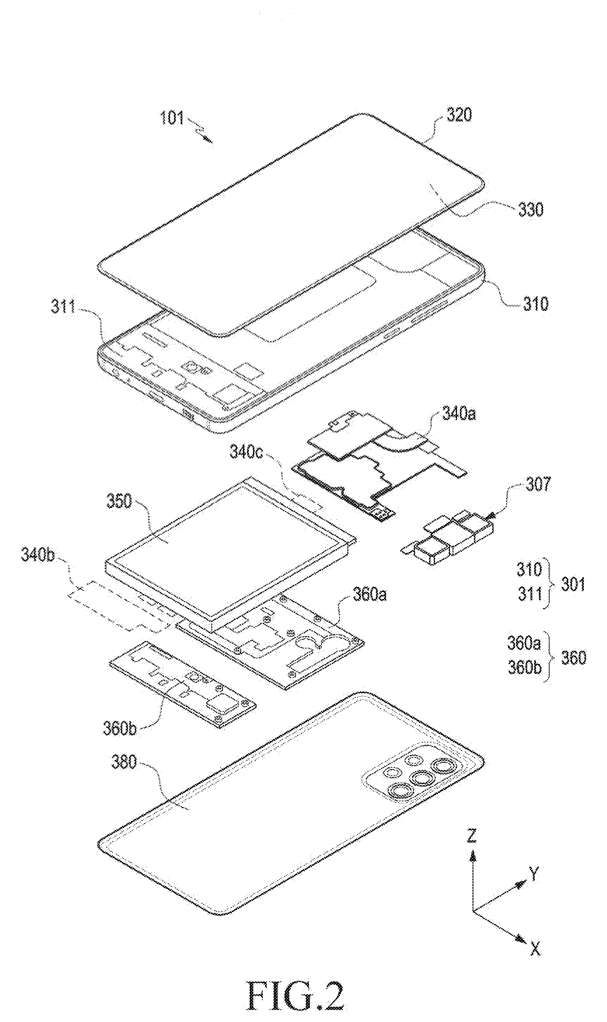

FIG. 2 is a rear exploded perspective view illustrating an electronic device according to an embodiment of the disclosure.

Referring to FIG. 2, an electronic device 101 (e.g., the electronic device 101 of FIG. 1) may include a side structure 310, a first supporting member 311 (e.g., a bracket), a front plate 320, a display panel 330, at least one printed circuit board (or substrate assembly) 340a or 340b, a battery 350, a second supporting member 360 (e.g., a rear case), a camera assembly 307, and a rear plate 380. When the plurality of printed circuit boards 340a and 340b are included, the electronic device 101 may include at least one flexible printed circuit board 340c to electrically connect different printed circuit boards. For example, the printed circuit boards 340a and 340b may include a first circuit board 340a disposed above the battery 350 and a second circuit board 340b disposed under the battery 350, and the flexible circuit board 340c may electrically connect the first circuit board 340a and the second circuit board 340b.

According to an embodiment, the electronic device 101 may exclude at least one (e.g., the first supporting member 311 or the second supporting member 360) of the components or may add other components. At least one of the components of the electronic device 101 may be the same or similar to at least one of the components of the electronic device 101 of FIG. 1 and no duplicate description is made below.

At least a portion of the first supporting member 311 may be provided in a flat plate shape. In an embodiment, the first supporting member 311 may be disposed inside the electronic device 101 to be connected with the side structure 310 or integrated with the side structure 310. The first supporting member 311 may be formed of, e.g., a metallic material and/or non-metallic material (e.g., polymer). When the first supporting member 311 is at least partially formed of a metallic material, a portion of the side structure 310 or the first supporting member 311 may function as an antenna. The display panel 330 may be coupled to one surface of the first supporting member 311, and the printed circuit boards 340a and 340b may be coupled to the opposite surface of the first supporting member 311. A processor, memory, and/or interface may be mounted on the printed circuit boards 340a and 340b. The processor may include one or more of, e.g., a central processing unit, an application processor, a graphic processing device, an image signal processor, a sensor hub processor, or a communication processor.

The first supporting member 311 may be referred to as a "supporting member." The housing 301 may include a supporting member 311. The supporting member 311 may face the front plate 320. The supporting member 311 may face the rear plate 380. The supporting member 311 may be coupled to the front plate 320 or the rear plate 380 through an adhesive member. The supporting member 311 may be formed of reinforced plastic or metal.

The supporting member 311 may include a support body 3111. The support body 3111 may have a flat plate shape. The support body 3111 may provide a space in which the battery 350 or the printed circuit boards 340a and 340b are disposed.

The supporting member 311 may include an end portion 3112. The end portion 3112 may be integrally formed with the support body 3111. The end portion 3112 may be formed along the circumference of the support body 3111. The end portion 3112 may extend along the circumference of the side structure 310. The end portion 3112 may be integrally formed with the side structure 310.

The front plate 320 may be coupled to the supporting member 311 through an adhesive member. The front plate 320 may be referred to as a "cover" or a "rear cover."

The rear plate 380 may be referred to as a "cover" or a "rear cover." The cover 380 may face the supporting member 311. A cover 380 may be formed of a reinforced plastic or a reinforced glass material on which a film is laminated.

The cover 380 may include a cover body 381. The cover body 381 may have a flat plate shape. The cover body 381 may face the support body 3111.

The cover 380 may include a cover edge 382. The cover edge 382 may be integrally formed with the cover body 381. The cover edge 382 may extend in a direction in which the end portion 3112 of the supporting member 311 extends. The cover edge 382 may face the end portion 3112 of the supporting member 311.

According to an embodiment, the first supporting member 311 and the side structure 310 may be collectively referred to as a front case or a housing 301. According to an embodiment, the housing 301 may be generally understood as a structure for receiving, protecting, or disposing the printed circuit boards 340a and 340b or the battery 350.

In an embodiment, the housing 301 may be understood as including a structure that the user may visually or tactfully recognize from the outside of the electronic device 101, e.g., the side structure 310, the front plate 320, and/or the rear plate 380. The housing 301 may include a side structure 310, a first supporting member 311, a front plate 320, and a rear plate 380.

In an embodiment, the first supporting member 311 may be disposed between the front plate 320 and the rear plate 380 and may function as a structure for placing an electrical/electronic component, such as the printed circuit boards 340a and 340b or the camera assembly 307.

The memory may include, e.g., volatile or non-volatile memory.

The interface may include, e.g., a high definition multimedia interface (HDMI), a universal serial bus (USB) interface, a secure digital (SD) card interface, and/or an audio interface. The interface may, e.g., electrically or physically connect the electronic device 101 to an external electronic device, and may include a USB connector, an SD card/MMC connector, or an audio connector.

The second supporting member 360 may include, e.g., an upper supporting member 360a and a lower supporting member 360b. In an embodiment, the upper supporting member 360a, together with a portion of the first supporting member 311, may be disposed to surround the printed circuit boards 340a and 340b (e.g., the first circuit board 340a). For example, the upper supporting member 360a of the second supporting member 360 may be disposed to face the first supporting member 311 with the first circuit board 340a interposed therebetween. In an embodiment, the lower supporting member 360b of the second supporting member 360 may be disposed to face the first supporting member 311 with the second circuit board 340b interposed therebetween. A circuit device (e.g., the processor 120, the communication module 190, or the memory 130 of FIG. 1) implemented in the form of an integrated circuit chip or various electrical/electronic components may be disposed on the printed circuit boards 340a and 340b. According to an embodiment, the printed circuit boards 340a and 340b may receive an electromagnetic shielding environment from the second supporting member 360. In an embodiment, the lower supporting member 360b may be utilized as a structure in which electrical/electronic components, such as a speaker module and an interface (e.g., a USB connector, an SD card/MMC connector, or an audio connector) may be disposed. In an embodiment, electrical/electronic components, such as a speaker module and an interface (e.g., a USB connector, an SD card/MMC connector, or an audio connector) may be disposed on an additional printed circuit board (not shown). For example, the lower supporting member 360b, together with the other part of the first supporting member 311, may be disposed to surround the additional printed circuit board.

The battery 350 may be a device for supplying power to at least one component of the electronic device 101. The battery 350 may include, e.g., a primary cell which is not rechargeable, a secondary cell which is rechargeable, or a fuel cell. At least a portion of the battery 350 may be disposed on substantially the same plane as the printed circuit boards 340a and 340b. The battery 350 may be integrally disposed inside the electronic device 101 or may be detachably disposed with the electronic device 101.

According to an embodiment, the camera assembly 307 may include at least one camera module. Inside the electronic device 101, the camera assembly 307 (or at least one camera module) may receive at least a portion of the light incident through the optical hole or camera windows. In an embodiment, the camera assembly 307 may be disposed on the first supporting member 311 in a position adjacent to the printed circuit boards 340a and 340b. In an embodiment, the camera module(s) of the camera assembly 307 may be generally aligned with any one of the camera windows and be a least partially surrounded by the second supporting member 360 (e.g., the upper supporting member 360a).

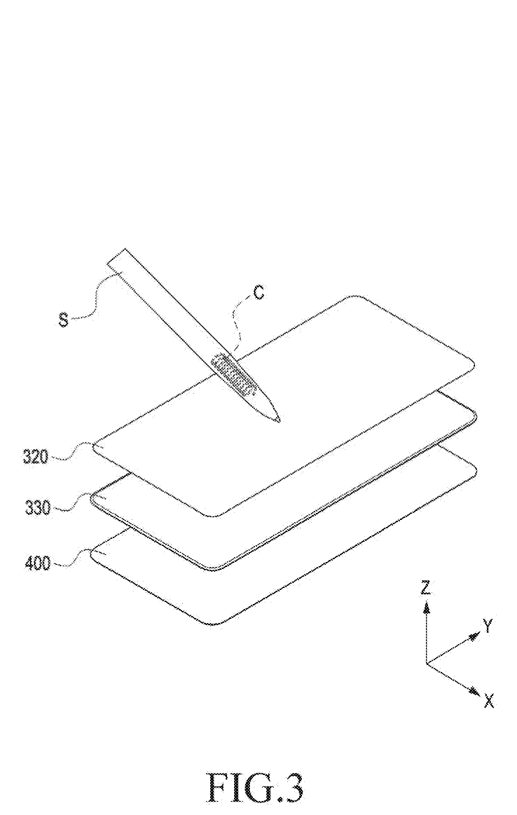

FIG. 3 illustrates an input module S (e.g., a stylus) and a digitizer 400 according to an embodiment of the disclosure. The input module S according to an embodiment of the disclosure may be a stylus pen S.

Referring to FIG. 3, an electronic device (e.g., the electronic device 101 of FIGS. 1 and 2) according to an embodiment of the disclosure may include a display panel 330 and a cover 320 covering the display panel 330. The cover 320 may be adhered to an outer surface of the display panel 330 to protect the display panel 330. The cover 320 may be formed of at least partially transparent material.

An electronic device according to an embodiment of the disclosure may include a digitizer 400 facing an inner surface of the display panel 330. The digitizer 400 may be disposed beneath the display panel 330. The digitizer 400 may be covered by the display panel 330.

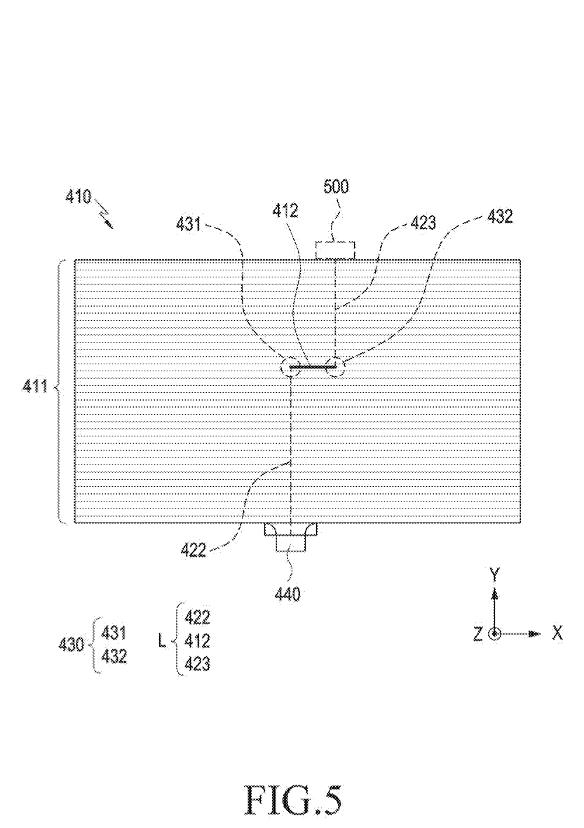

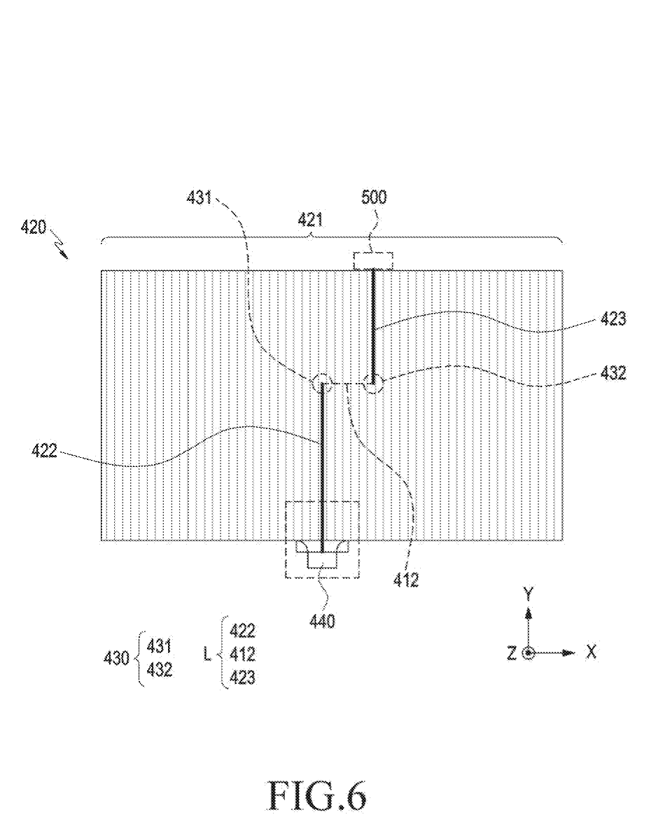

A stylus S (e.g., the input module 150 of FIG. 1) according to an embodiment of the disclosure may include a coil C that forms a magnetic field F, F. The coil C may be disposed inside the stylus S. The digitizer 400 may include a plurality of coils (e.g., the coils 411 of FIG. 5 and the coils 421 of FIG. 6) through which a current induced by the magnetic field of the coil C flows. When the position of the stylus S generating the magnetic field moves, the digitizer 400 may detect a change in the magnetic field.

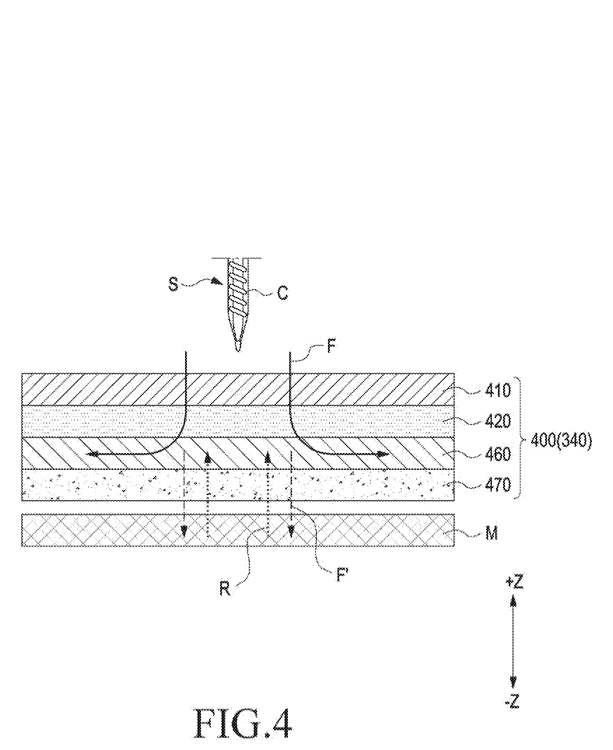

FIG. 4 is a cross-sectional view illustrating a digitizer 400 according to an embodiment of the disclosure.

Referring to FIGS. 3 and 4, a digitizer 400 according to an embodiment of the disclosure may include conductive layers 410 and 420 through which the magnetic field F of the stylus S passes.

The conductive layers 410 and 420 according to an embodiment of the disclosure may be disposed beneath the display panel 330. The conductive layers 410 and 420 may include a second conductive layer 420 and a first conductive layer 410 disposed between the display panel 330 and the second conductive layer 420. As an example, the conductive layers 410 and 420 may be a substrate on which the plurality of coils are formed. The plurality of coils disposed in the conductive layers 410 and 420 is described below in detail.

A digitizer 400 according to an embodiment of the disclosure may include a shielding layer 460. The shielding layer 460 may be disposed beneath the conductive layers 410 and 420. The shielding layer 460 may be disposed between the conductive layers 410 and 420 and a ground layer 470. The shielding layer 460 may minimize penetration of a magnetic field outside the digitizer 400 into the conductive layers 410 and 420. As an example, the shielding layer 460 may include magnetic metal powder (MMP).

According to an embodiment of the disclosure, a portion F of the magnetic field F, F’ formed by the stylus S may pass through the shielding layer 460 and then induce an eddy current in an external metal M disposed outside the digitizer 400. In this case, the shielding layer 460 may minimize penetration of a reverse magnetic field R formed by the eddy current flowing in the external metal M into the conductive layers 410 and 420.

A digitizer 400 according to an embodiment of the disclosure may include a ground layer 470. The ground layer 470 may be disposed beneath the shielding layer 460. The ground layer 470 may be electrically connected to a conductive line disposed in the conductive layers 410 and 420. The ground layer 470 may ground a conductive line disposed in the conductive layers 410 and 420. The ground layer 470 is described below in detail.

FIGS. 5 and 6 illustrate a portion of a digitizer 400 and an electronic module 500 according to various embodiments of the disclosure.

Referring to FIGS. 5 and 6, a digitizer 400 according to an embodiment of the disclosure may include a first conductive layer 410 including a plurality of first coils 411, and may include a second conductive layer 420 including a plurality of second coils 421.

Referring to FIG. 5, the plurality of first coils 411 according to an embodiment of the disclosure may have a shape elongated in one direction. As an example, the first coils 411 may have a rectangular shape elongated in an X-axis direction. The direction in which the first coils 411 are elongated (e.g., the X-axis direction) may be referred to as a length direction of the first coil 411.

The plurality of first coils 411 according to an embodiment of the disclosure may be sequentially disposed in one direction. As an example, the plurality of first coils 411 may be disposed in a Y-axis direction. The direction in which the plurality of first coils 411 are elongated may intersect the direction in which the plurality of first coils 411 are sequentially disposed. For example, the direction in which the plurality of first coils 411 are elongated (e.g., the X-axis direction) may be perpendicular to the direction in which the plurality of first coils 411 are sequentially disposed (e.g., the Y-axis direction). The plurality of first coils 411 may at least partially overlap each other.

Referring to FIG. 6, the plurality of second coils 421 according to an embodiment of the disclosure may have a shape elongated in one direction. As an example, the second coils 421 may have a rectangular shape elongated in a Y-axis direction. The direction in which the second coils 421 are elongated (e.g., the Y-axis direction) may be referred to as a length direction of the second coil 421.

The plurality of second coils 421 according to an embodiment of the disclosure may be sequentially disposed in one direction. As an example, the plurality of second coils 421 may be disposed in an X-axis direction. The direction in which the plurality of second coils 421 are elongated may intersect the direction in which the plurality of second coils 421 are sequentially disposed. For example, the direction in which the plurality of second coils 421 are elongated (e.g., the Y-axis direction) may be perpendicular to the direction in which the plurality of second coils 421 are sequentially disposed (e.g., the X-axis direction). The plurality of second coils 421 may at least partially overlap each other.

According to an embodiment of the disclosure, a current induced by the magnetic field F generated by the stylus S may flow in the first coils 411 and the second coils 421. Based on a comparison of current values flowing in the first coils 411 and the second coils 421, a relative position of the stylus S with respect to the digitizer 400 may be determined. For example, the position of the coil 411 having the largest current magnitude among the first coils 411 may be understood as the position of the stylus S in the direction in which the first coils 411 are sequentially disposed, and the position of the coil 421 having the largest current magnitude among the second coils 421 may be understood as the position of the stylus S in the direction in which the second coils 421 are sequentially disposed.

A digitizer 400 according to an embodiment of the disclosure may include a connector 440 to which the plurality of coils 411 and 421 are connected. The connector 440 may be connected to a processor (e.g., the processor 120 of FIG. 1) of the electronic device. The connector 440 may be connected to one side of the first conductive layer 410. The connector 440 may be connected to one side of the second conductive layer 420. The connector 440 may be connected to electronic components (e.g., the processor 120 and the battery 189 of FIG. 1 and/or the substrate (printed circuit board 340a) of FIG. 2) of the electronic device 101.

An electronic device according to an embodiment of the disclosure may include at least one electronic module 500. The electronic module 500 may be disposed around an outer edge of the first conductive layer 410 or the second conductive layer 420. The electronic module 500 may be disposed around an outer edge of the display panel 330 (e.g., FIG. 3). As an example, the electronic module 500 may be a camera, a microphone, a universal serial bus (USB) port, or the like.

The electronic module 500 according to an embodiment of the disclosure may be disposed offset with respect to the connector 440. For example, the electronic module 500 and the connector 440 may be spaced apart in the length direction of the first coil 411 (e.g., the X-axis direction) and the length direction of the second coil 421 (e.g., the Y-axis direction).

A digitizer 400 according to an embodiment of the disclosure may include a signal line L connecting the connector 440 and the electronic module 500. For example, a control signal for the electronic module 500 sent from the processor (e.g., the processor 120 of FIG. 1) may be transmitted to the electronic module 500 through the connector 440 and the signal line L.

Referring to FIG. 5, a signal line L according to an embodiment of the disclosure may include a first trace 412 disposed in the first conductive layer 410. The first trace 412 may be positioned between traces constituting the plurality of first coils 411. The first trace 412 may not contact the plurality of first coils 411. The first trace 412 may extend along the length direction of the first coil 411.

Referring to FIG. 6, a signal line L according to an embodiment of the disclosure may include traces 422 and 423 disposed in the second conductive layer 420. The traces 422 and 423 disposed in the second conductive layer 420 may include a second trace 422 connected to the connector 440 and a third trace 423 connected to the electronic module 500. The second trace 422 and the third trace 423 may be positioned between traces constituting the plurality of second coils 421. The second trace 422 and the third trace 423 may not contact the plurality of second coils 421. The second trace 422 and the third trace 423 may extend along the length direction of the second coil 421.

A signal line L according to an embodiment of the disclosure may include a connecting portion 430. The connecting portion 430 may electrically connect the first conductive layer 410 and the second conductive layer 420. As an example, the connecting portion 430 may be a via-hole penetrating the conductive layers 410 and 420.

The connecting portion 430 according to an embodiment of the disclosure may include a first via 431 electrically connecting the first trace 412 and the second trace 422, and a second via 432 electrically connecting the first trace 412 and the third trace 423. Through the connecting portion 430, the traces 422, 412, and 423 respectively disposed in the first conductive layer 410 and the second conductive layer 420 may be electrically connected to each other.

The signal line L according to an embodiment of the disclosure may be disposed inside the digitizer 400. The second trace 422 and the third trace 423 may extend along the length direction of the second coil 421. The first trace 412 may extend along the length direction of the first coil 411. The first via 431 and the second via 432 may be spaced apart from the traces constituting the first coils 411 and the second coils 421.

Accordingly, the signal line L may provide a shortest path extending from the connector 440 to the electronic module 500 while avoiding the plurality of coils 411 and 421. Accordingly, a problem (e.g., noise) occurring in a signal transmission process may be minimized.

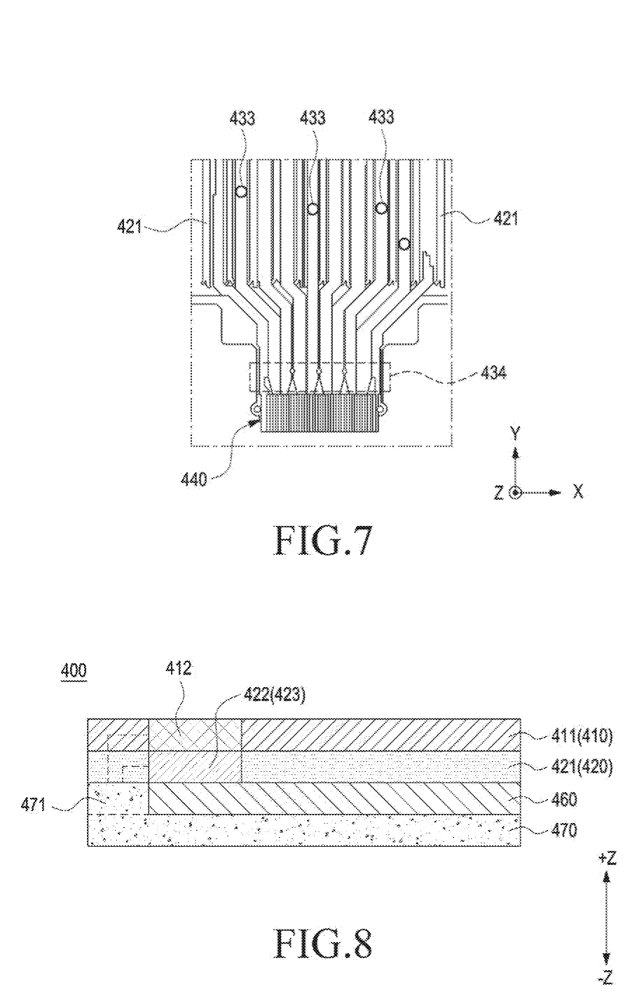

FIG. 7 is an enlarged view illustrating a portion of FIG. 6 according to an embodiment of the disclosure.

Referring to FIG. 7, a digitizer 400 according to an embodiment of the disclosure may include via-holes 433 and 434. The first conductive layer 410 and the second conductive layer 420 may be electrically connected through the via-holes 433 and 434. As an example, the first coil 411 and the second coil 421 may be electrically connected through the via-holes 433 and 434.

FIG. 8 is a cross-sectional view illustrating a digitizer 400 according to an embodiment of the disclosure.

Referring to FIG. 8, a digitizer 400 according to an embodiment of the disclosure may include a shielding layer 460 that minimizes an influence of an external magnetic field. The shielding layer 460 may be disposed beneath the second conductive layer 420. The shielding layer 460 may be disposed between the second conductive layer 420 and a ground layer 470. The shielding layer 460 may include a conductive member (e.g., magnetic metal powder (MMP)).

A digitizer 400 according to an embodiment of the disclosure may include a ground layer 470 that grounds the signal line L. The ground layer 470 may be disposed beneath the shielding layer 460. The ground layer 470 may be electrically connected to the signal line L. The ground layer 470 may be electrically connected to the first trace 412 disposed in the first conductive layer 410. The ground layer 470 may be electrically connected to the second and third traces 422 and 423 disposed in the second conductive layer 420.

The ground layer 470 according to an embodiment of the disclosure may include a connecting portion 471. The ground layer 470 may be electrically connected to the signal line L through the connecting portion 471 to ground the signal line L. The connecting portion 471 may be located around an edge portion of the digitizer 400. The connecting portion 471 may be electrically connected to an outer edge portion of the second conductive layer 420 and/or the first conductive layer 410.

The connecting portion 471 according to an embodiment of the disclosure may be located around the shielding layer 460. Unlike the embodiment of the disclosure, the connecting portion 471 may penetrate an outer edge portion of the shielding layer 460 and be electrically connected to the second conductive layer 420 and/or the first conductive layer 410.

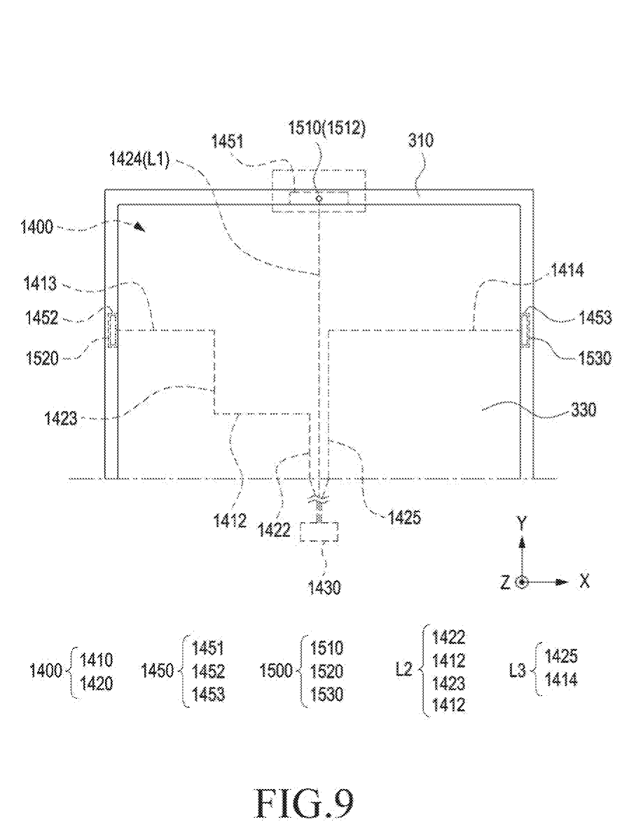

FIG. 9 illustrates a portion of an electronic device and a plurality of electronic modules 1500 according to an embodiment of the disclosure.

The descriptions of the components (the first conductive layer 410, the second conductive layer 420, the connecting portion 430, the connector 440, and the electronic module 500) described with reference to FIGS. 4 to 6 may be equally applied to the components having the same names (the first conductive layer 1410, the second conductive layer 1420, the connector 1430, the connecting portion, and the electronic module 1500) illustrated in FIG. 9, to the extent that they are not inconsistent with each other.

Referring to FIG. 9, the plurality of electronic modules 1500 according to an embodiment of the disclosure may be connected to a connector 1440 through signal lines L1, L2, and L3 disposed in a digitizer 1400.

The digitizer 1400 according to an embodiment of the disclosure may be disposed beneath the display panel 330. A frame 310 according to an embodiment of the disclosure may surround the display panel 330. The frame 310 may support the electronic modules 1500, the display panel 330, and/or the digitizer 1400.

According to an embodiment of the disclosure, the electronic modules 1500 may be located around an edge of the display panel 330. The electronic modules 1500 may be disposed around an edge of the digitizer 1400.

The digitizer 1400 according to an embodiment of the disclosure may include mounting portions 1450 formed at an outer edge of the first conductive layer 1410 and/or the second conductive layer 1420. The plurality of electronic modules 1500 may be disposed on the mounting portions 1450. However, as illustrated in FIG. 9, the electronic module 1500 and the mounting portion 1450 are not necessarily provided in plurality.

The mounting portion 1450 according to an embodiment of the disclosure may extend outward from an outer edge of the first conductive layer 1410 and/or the second conductive layer 1420. The mounting portion 1450 may include a first mounting portion 1451, a second mounting portion 1452, and a third mounting portion 1453. The first mounting portion 1451, the second mounting portion 1452, and the third mounting portion 1453 may be disposed along an outer edge of the first conductive layer 1410 and/or the second conductive layer 1420.

The electronic modules 1500 according to an embodiment of the disclosure may include a first electronic module 1510 disposed on the first mounting portion 1451. The electronic modules 1500 may include a second electronic module 1520 disposed on the second mounting portion 1452. The electronic modules 1500 may include a first electronic module 1530 disposed on the third mounting portion 1453.

A first signal line L1 according to an embodiment of the disclosure may be disposed in one of the first conductive layer 1410 and the second conductive layer 1420. As an example, FIG. 9 illustrates a case in which the first signal line L1 is disposed in the second conductive layer 1420. The first signal line L1 may be referred to as a trace 1424. The first signal line L1 may extend along the length direction (e.g., the Y-axis direction) of the coils (e.g., the second coil 421 of FIG. 6) disposed in the second conductive layer 1420. The first signal line L1 may be spaced apart from the coils (e.g., the second coil 421 of FIG. 6) disposed in the second conductive layer 1420. The first signal line L1 may electrically connect the connector 1440 and the first electronic module 1510. The first signal line L1 may extend substantially straight.

A second signal line L2 according to an embodiment of the disclosure may include a plurality of traces 1422, 1412, 1423, and 1413. Some of the plurality of traces 1422, 1412, 1423, and 1413 (1422 and 1423) may be disposed in the second conductive layer 1420. Other ones of the plurality of traces 1422, 1412, 1423, and 1413 (1412 and 1413) may be disposed in the first conductive layer 1410.

The second signal line L2 according to an embodiment of the disclosure may include a connecting portion (e.g., the connecting portion 430 of FIGS. 5 and 6) electrically connecting the first conductive layer 1410 and the second conductive layer 1420. The traces 1422 and 1423 disposed in the second conductive layer 1420 and the traces 1412 and 1413 disposed in the first conductive layer 1410 may be electrically connected through the connecting portion (e.g., the connecting portion 430 of FIGS. 5 and 6).

A third signal line L3 according to an embodiment of the disclosure may include a plurality of traces 1425 and 1414. Some of the plurality of traces 1425 and 1414 (1425) may be disposed in the second conductive layer 1420. Other ones of the plurality of traces 1425 and 1414 (1414) may be disposed in the first conductive layer 1410.

The third signal line L3 according to an embodiment of the disclosure may include a connecting portion (e.g., the connecting portion 430 of FIGS. 5 and 6) electrically connecting the first conductive layer 1410 and the second conductive layer 1420. The trace 1425 disposed in the second conductive layer 1420 and the trace 1414 disposed in the first conductive layer 1410 may be electrically connected through the connecting portion (e.g., the connecting portion 430 of FIGS. 5 and 6).

Among the plurality of traces 1412, 1413, 1414, 1422, 1423, and 1425 constituting the second signal line L2 and the third signal line L3 according to an embodiment of the disclosure, the traces 1412, 1413, and 1414 disposed in the first conductive layer 1410 may extend along the length direction (e.g., the X-axis direction) of the coils (e.g., the first coil 411 of FIG. 5) disposed in the first conductive layer 1410. The traces 1412, 1413, and 1414 disposed in the first conductive layer 1410 may be spaced apart from the coils (e.g., the first coil 411 of FIG. 5) disposed in the first conductive layer 1410.

Among the plurality of traces 1412, 1413, 1414, 1422, 1423, and 1425 constituting the second signal line L2 and the third signal line L3 according to an embodiment of the disclosure, the traces 1422, 1423, and 1425 disposed in the second conductive layer 1420 may extend along the length direction (e.g., the Y-axis direction) of the coils (e.g., the second coil 421 of FIG. 6) disposed in the second conductive layer 1420. The traces 1422, 1423, and 1425 disposed in the second conductive layer 1420 may be spaced apart from the coils (e.g., the second coil 421 of FIG. 6) disposed in the second conductive layer 1420.

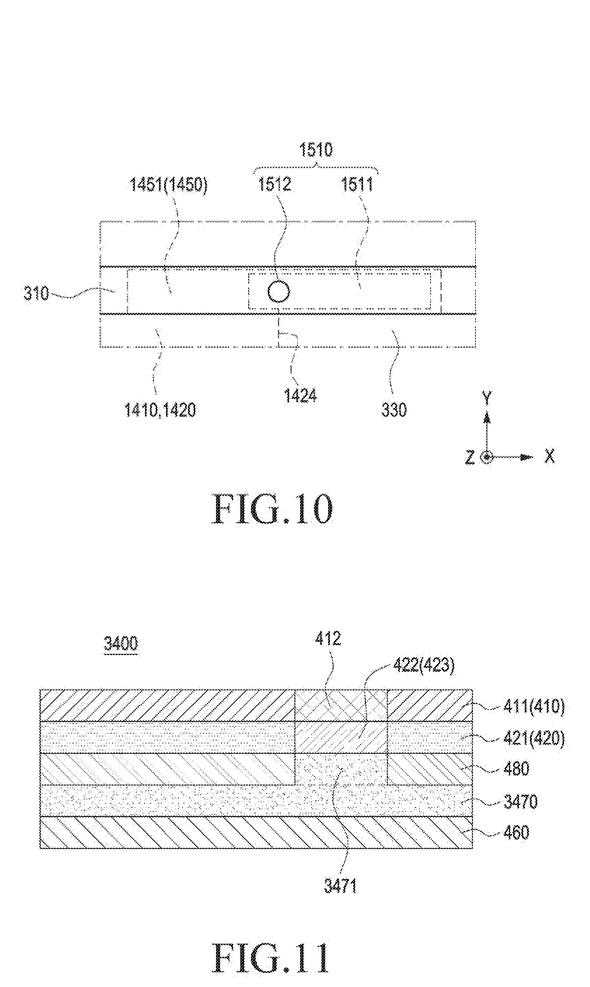

FIG. 10 is an enlarged view illustrating a portion of FIG. 9 according to an embodiment of the disclosure. FIG. 10 is an enlarged view illustrating a portion of the first electronic module 1510 of FIG. 9.

Referring to FIGS. 9 and 10, the first electronic module 1510 may include an output portion 1512 and a substrate 1511.

The output portion 1512 of the first electronic module 1510 according to an embodiment of the disclosure may be exposed to an outside of the frame 310. As an example, the first electronic module 1510 may be a camera module 1510, and the output portion 1512 may be a lens portion of a camera.

The substrate 1511 of the first electronic module 1510 according to an embodiment of the disclosure may be disposed on the mounting portion 1451 of the digitizer 1400. The substrate 1511 may be connected to the signal line 1424, L1. The frame 310 may cover at least a portion of the substrate 1511. A circuit and/or an integrated circuit chip for controlling an operation of the first electronic module 1510 may be disposed on the substrate 1511. As an example, a control signal sent from a processor (e.g., the processor 120 of FIG. 1) of the electronic device may be sequentially transmitted through the connector 1440 and the signal line 1424 to the substrate 1511.

FIG. 11 is a cross-sectional view illustrating a digitizer 3400 according to an embodiment of the disclosure.

The digitizer 3400 according to an embodiment of the disclosure may include an insulation layer 480. The insulation layer 480 may be disposed beneath the second conductive layer 420. The insulation layer 480 may be disposed between the second conductive layer 420 and a ground layer 3470. The insulation layer 480 may block electrical conduction between the second conductive layer 420 and the ground layer 3470.

The digitizer 3400 according to an embodiment of the disclosure may include a ground layer 3470. The ground layer 3470 may ground the signal line L (e.g., the signal line L of FIGS. 5 and 6). The ground layer 3470 may be electrically connected to the signal line L (e.g., the signal line L of FIGS. 5 and 6). The ground layer 3470 may include a connecting portion 3471 electrically connected to the traces 422 and 423 of the signal line L.

The connecting portion 3471 of the ground layer 3470 according to an embodiment of the disclosure may penetrate the insulation layer 480 or be electrically connected to the second conductive layer 420 through an outer edge of the insulation layer 480. The connecting portion 3471 of the ground layer 3470 may ground the signal lines 422, 423, and 412 through the insulation layer 480.

As described above, the digitizers 400, 1400, 2400, and 3400 according to an embodiment of the disclosure may include at least one adhesive layer (not illustrated). The adhesive layers may include an adhesive member (not illustrated). The adhesive layers may be disposed between the conductive layers 410, 420, 1410, 1420, 2410, and 2420, the shielding layer 460, and the ground layers 470 and 3470 to adhere two adjacent layers to each other. The adhesive layers may include an insulating member (not illustrated). The adhesive layers may block electrical conduction between the two adjacent layers.

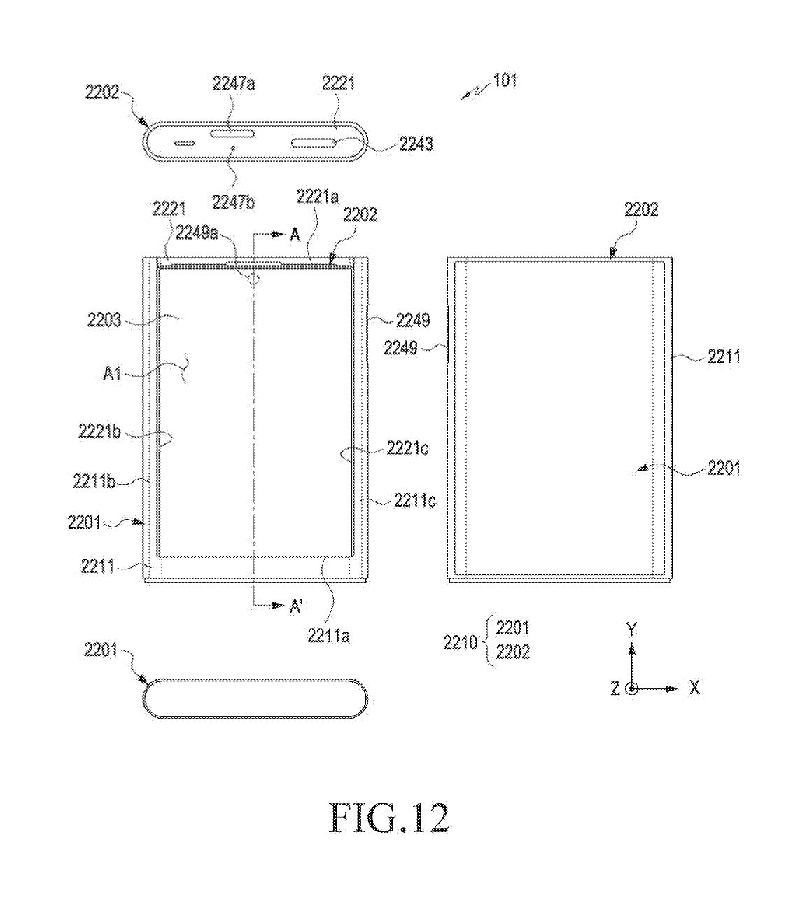

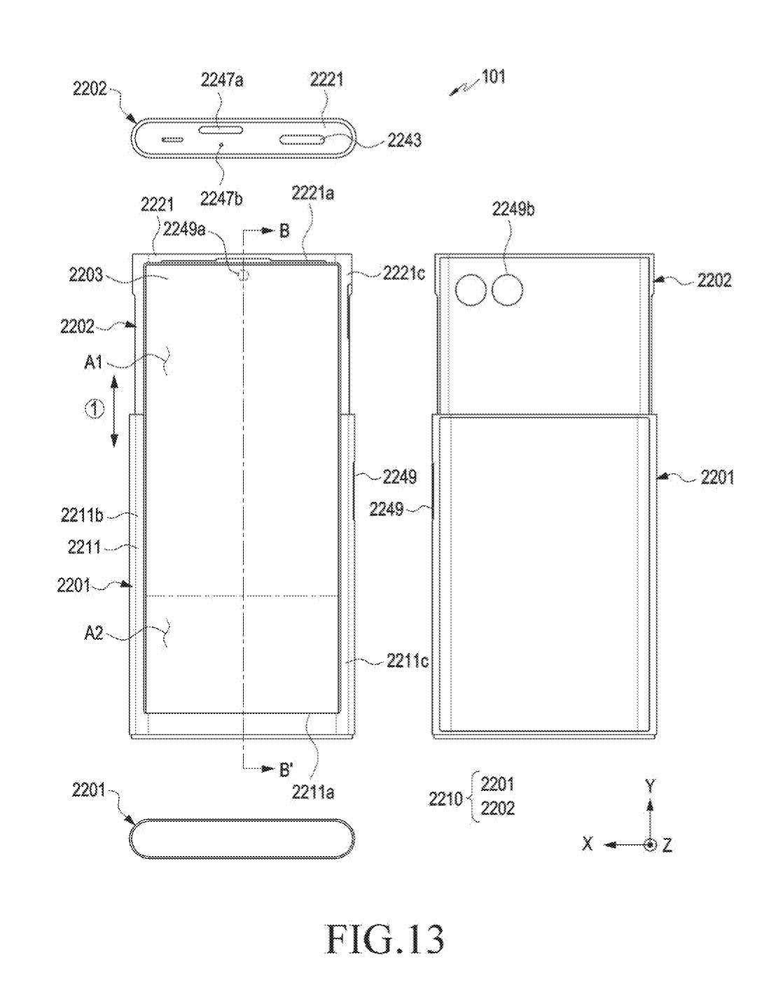

FIG. 12 is a view illustrating a state in which a second display area A2 of a display 2203 is received in a housing 2210 according to an embodiment of the disclosure. FIG. 13 is a view illustrating a state in which a second display area A2 of a display 2203 is exposed to the outside of a housing 2210 according to an embodiment of the disclosure.

FIGS. 12 and 13 illustrate a state in which a display 2203 (e.g., a flexible display or a rollable display) extends in a length direction (e.g., a +Y direction) when viewing the electronic device 101 from the front. However, the extending direction of the display 2203 is not limited to one direction (e.g., +Y direction). For example, the electronic device 101 may be designed such that the display 2203 may be extendable in an upward direction (+Y direction), a rightward direction (e.g., a +X direction), a leftward direction (e.g., a −X direction), and/or a downward direction (e.g., a −Y direction).

The state illustrated in FIG. 12 may be referred to as a slide in state of the electronic device 101, or a closed state in which a second display region A2 of the display 2203 is closed. The state illustrated in FIG. 13 may be referred to as a slide out state of the electronic device 101, or an opened state in which the second display region A2 of the display 2203 is opened.

Referring to FIGS. 12 and 13, the electronic device 101 may include a housing 2210. The housing 2210 may include a first housing 2201 and a second housing 2202 disposed to be movable relative to the first housing 2201. According to an embodiment, the electronic device 101 may be interpreted as having a structure in which the first housing 2201 is disposed to be slidable with respect to the second housing 2202. According to an embodiment, the second housing 2202 may be disposed to perform reciprocating motion by a predetermined distance in a predetermined direction with respect to the first housing 2201, for example, a direction indicated by an arrow ①.

According to an embodiment, the second housing 2202 may be referred to as a slide portion or a slide housing, and may be movable relative to the first housing 2201. According to an embodiment, various electrical and electronic components, such as a circuit board or a battery, may be disposed inside the second housing 2202.

According to an embodiment, the first housing 2201 may receive a motor, a speaker, a sim socket, and/or a sub circuit board electrically connected with a main circuit board. The second housing 2202 may receive a main circuit board on which electric components, such as an application processor (AP) and a communication processor (CP) are mounted.

According to an embodiment, the first housing 2201 may include a first cover member 2211 (e.g., a main case). The first cover member 2211 may include a 1-1th sidewall 2211a, a 1-2th sidewall 2211b extending from the 1-1th sidewall 2211a, and a 1-3th sidewall 2211c extending from the 1-1th sidewall 2211a and substantially parallel to the 1-2th sidewall 2211b. According to an embodiment, the 1-2th side wall 2211b and the 1-3th side wall 2211c may be formed substantially perpendicular to the 1-1th side wall 2211a.

According to an embodiment, the 1-1th sidewall 2211a, the 1-2th sidewall 2211b, and the 1-3th sidewall 2211c of the first cover member 2211 may be formed in a shape in which one side (e.g., a front surface) of the first cover member 2211 is open to accommodate (or surround) at least a portion of the second housing 2202. For example, at least a portion of the second housing 2202 may be surrounded by the first housing 2201 and be slid in the direction parallel to the first surface, e.g., arrow ① direction, while being guided by the first housing 2201. According to an embodiment, the 1-1th sidewall 2211a, the 1-2th sidewall 2211b, and/or the 1-3th sidewall 2211c of the first cover member 2211 may be integrally formed. According to an embodiment, the 1-1th sidewall 2211a, the 1-2th sidewall 2211b, and/or the 1-3th sidewall 2211c of the first cover member 2211 may be formed as separate structures and be combined or assembled.

According to an embodiment, the first cover member 2211 may be formed to surround at least a portion of the display 2203. For example, at least a portion of the display 2203 may be formed to be surrounded by the 1-1th sidewall 2211a, the 1-2th sidewall 2211b, and/or the 1-3th sidewall 2211c of the first cover member 2211.

According to an embodiment, the second housing 2202 may include a second cover member 2221 (e.g., a slide plate). The second cover member 2221 may have a plate shape and include a first surface supporting internal components. For example, the second cover member 2221 may support at least a portion of the display 2203 (e.g., the first display area A1). According to an embodiment, the second cover member 2221 may be referred to as a front cover.

According to an embodiment, the second cover member 2221 may include a 2-1th sidewall 2221a, a 2-2th sidewall 2221b extending from the 2-1th sidewall 2221a, and a 2-3th sidewall 2221c extending from the 2-1th sidewall 2221a and substantially parallel to the 2-2th sidewall 2221b. According to an embodiment, the 2-2th sidewall 2221b and the 2-3th sidewall 2221c may be formed substantially perpendicular to the 2-1th sidewall 2221a.

According to various embodiments, as the second housing 2202 moves in a first direction (e.g., direction ①) parallel to the 2-2th sidewall 2221b or the 2-3th sidewall 2221c, the slide-in state and slide-out state of the electronic device 101 may be formed. In the slide-in state of the electronic device 101, the second housing 2202 may be positioned at a first distance from the 1-1th sidewall 2211a of the first housing 2201. In the slide-out state of the electronic device 101, the second housing 2202 may move to be positioned at a second distance larger than the first distance from the 1-1th sidewall 2211a of the first housing 2201. In an embodiment, in the slide-in state of the electronic device 101, the first housing 2201 may be formed to surround a portion of the 2-1th sidewall 2221a.

According to an embodiment, the electronic device 101 may have an intermediate state between the slide-in state (e.g., fully opened state) of FIG. 2 and the slide-out state (e.g., fully closed state) of FIG. 3. The distance between the 1-1th sidewall 2211a and the 2-1th sidewall 2221a in the intermediate state of the electronic device 101 may be shorter than the distance between the 1-1th sidewall 2211a and the 2-1th sidewall 2221a of the electronic device 101 in the fully open state and be longer than the distance between the 1-1th sidewall 2211a and the 2-1th sidewall 2221a of the electronic device 101 in the fully closed state. According to an embodiment, as at least a portion of the display 2203 slides in the intermediate state of the electronic device 101, the area exposed to the outside may vary. For example, in the intermediate state of the electronic device 101, the ratio of the width (length in the X direction) to the height (length in the Y direction) of the display 2203 and/or the distance between the 1-1th sidewall 2211a and the 2-1th sidewall 2221a may be changed based on the slide of the electronic device 101.

According to an embodiment, the electronic device 101 may include a display 2203, a key input device 2245, a connector hole 2243, audio modules 2247a and 2247b, or camera modules 2249a and 249b. According to an embodiment, the electronic device 101 may further include an indicator (e.g., a light emitting diode (LED) device) or various sensor modules.

According to various embodiments, the display 2203 may include a first display area A1 and a second display area A2 configured to be exposed to the outside of the electronic device 101 based on the slide of the second housing 2202. According to an embodiment, the first display area A1 may be disposed on the second housing 2202. For example, the first display area A1 may be disposed on the second cover member 2221 of the second housing 2202. According to an embodiment, the second display area A2 may extend from the first display area A1, and the second display area A2 may be received in the first housing 2201 or visually exposed to the outside of the electronic device 101 as the second housing 2202 slides relative to the first housing 2201. According to an embodiment, as the electronic device 101 changes from the slide-out state to slide-in state, the display 2203 may expand in the lower direction (e.g., -Y direction) of the electronic device 101. For example, in the slide-out state of the electronic device 101, the second display area A2 may be visually exposed under the display 2203 (e.g., in the -Y direction). According to an embodiment, as the electronic device 101 changes from the slide-out state to slide-in state, the display 2203 may extend in the upper direction (e.g., +Y direction) of the electronic device 101. For example, in the slide-out state of the electronic device 101, the second display area A2 may be visually exposed above the display 2203 (e.g., in the +Y direction).

According to an embodiment, the second display area A2 may be received in the space positioned inside the first housing 2201 or exposed to the outside of the electronic device 101 while being substantially guided by one area of the first housing 2201. According to an embodiment, the second display area A2 may move based on a slide of the second housing 2202 in the first direction (e.g., the direction indicated by the arrow ①). For example, while the second housing 2202 slides, a portion of the second display area A2 may be deformed into a curved shape in a position corresponding to the curved surface 2213a of the first housing 2201.

According to an embodiment, as viewed from above the second cover member 2221 (e.g., front cover), if the electronic device 101 changes from the slide-in state to slide-out state (e.g., if the second housing 2202 slides to extend from the first housing 2201), the second display area A2 may be gradually exposed to the outside of the first housing 2201 and, together with the first display area A1, form a substantially flat surface. According to an embodiment, the display 2203 may be coupled with or disposed adjacent to a touch detection circuit, a pressure sensor capable of measuring the strength (pressure) of touches, and/or a digitizer for detecting a magnetic field-type stylus pen. According to an embodiment, irrespective of the slide-in state or slide-out state of the electronic device 101, the exposed portion of the second display area A2 may be positioned on a portion of the first housing, and a portion of the second display area A2 may remain in the curved shape in the position corresponding to the curved surface 2213a.

According to an embodiment, the key input device 2245 may be positioned in an area of the housing 2210 (e.g., the first housing 2201 and/or second housing 2202). Depending on the appearance and usage state, the electronic device 101 may be designed such that the illustrated key input device 2245 is omitted or includes additional key input device(s). According to an embodiment, the electronic device 101 may include a key input device (not shown), e.g., a home key button or a touchpad disposed around the home key button. According to an embodiment, at least a portion of the key input device 2245 may be disposed on the 1-1th sidewall 2211a, the 1-2th sidewall 2211b, or the 1-3th sidewall 2211c of the first housing 2201. According to an embodiment, at least a portion of the key input device 2245 may be disposed on the 2-1th sidewall 2221a, the 2-2th sidewall 2221b, and/or the 2-3th sidewall 2221c of the second housing 2202.

According to an embodiment, the connector hole 2243 may be omitted or may accommodate a connector (e.g., a universal serial bus (USB) connector) for transmitting and receiving power and/or data with an external electronic device. According to an embodiment (not shown), the electronic device 101 may include a plurality of connector holes 2243, and some of the plurality of connector holes 2243 may function as connector holes for transmitting/receiving audio signals with an external electronic device. In the illustrated embodiment, the connector hole 2243 is disposed in the second housing 2202, but is not limited thereto. For example, the connector hole 2243 or a connector hole not shown may be disposed in the first housing 2201.

According to an embodiment, the audio modules 2247a and 247b may include at least one speaker hole 2247a or at least one microphone hole 2247b. One of the speaker holes 2247a may be provided as a receiver hole for voice calls, and another may be provided as an external speaker hole. The electronic device 101 includes a microphone for obtaining sound, and the microphone may acquire sound external to the electronic device 101 through the microphone hole 2247b. According to an embodiment, the electronic device 101 may include a plurality of microphones to detect the direction of sound. According to an embodiment, the electronic device 101 may include an audio module in which the speaker hole 2247a and the microphone hole 2247b are implemented as a single hole, or may include a speaker excluding the speaker hole 2247a (e.g., piezo speaker). According to an embodiment, the speaker hole 2247a and the microphone hole 2247b may be positioned in the first housing 2201 and/or the second housing 2202.

According to an embodiment, the camera modules 2249a and 249b may include a first camera module 2249a (e.g., front camera) and/or a second camera module 2249b (e.g., rear camera). According to an embodiment, the electronic device 101 may include at least one of a wide-angle camera, a telephoto camera, or a close-up camera. According to an embodiment, the electronic device 101 may measure the distance to the subject by including an infrared projector and/or an infrared receiver. The camera modules 2249a, 2249b may include one or more lenses, an image sensor, and/or an image signal processor. The first camera module 2249a may be disposed to face in the same direction as the display 2203. For example, the first camera module 2249a may be disposed in an area around the first display area A1 or overlapping the display 2203. When disposed in the area overlapping the display 2203, the first camera module 2249a may capture the subject through the display 2203. According to an embodiment, the first camera module 2249a may not be visually exposed to a screen display area (e.g., the first display area A1) and may include an under display camera (UDC). According to an embodiment, the second camera module 2249b may capture the subject in a direction opposite to the first display area A1. According to an embodiment, the first camera module 2249a and/or the second camera module 2249b may be disposed on the second housing 2202. According to an embodiment, a plurality of second camera modules 2249b may be formed to provide various arrays. For example, the plurality of second camera modules 2249b may be arranged along a width direction (X-axis direction) that is substantially perpendicular to the sliding direction (e.g., Y-axis direction) of the electronic device 101. As another example, the plurality of second camera modules 2249b may be arranged along the sliding direction (e.g., Y-axis direction) of the electronic device 101. As another example, the plurality of second camera modules 2249b may be arranged along N * M rows and columns like a matrix.

According to an embodiment, the second camera module 2249b is not visually exposed to the outside of the electronic device 101 in the slide-in state of the electronic device 101 and, in the slide-out state of the electronic device 101, may capture the outside of the electronic device 101. According to an embodiment, the second camera module 2249b may capture the outside of the electronic device 101 in the slide-in state and slide-out state of the electronic device 101. For example, at least a portion of the housing 2210 may be substantially transparent. The second camera module 2249b may capture the outside of the electronic device 101 through the first rear plate 2215 and/or the second rear plate 2225.

According to an embodiment, an indicator (not shown) of the electronic device 101 may be disposed on the first housing 2201 or the second housing 2202, and the indicator may include a light emitting diode to provide state information about the electronic device 101 as a visual signal. A sensor module (not illustrated) of the electronic device 101 may generate an electrical signal or data value corresponding to an internal operation state of the electronic device 101 or an external environmental state. The sensor module may include, for example, a proximity sensor, a fingerprint sensor, or a biometric sensor (e.g., an iris/face recognition sensor or a heartrate monitor (HRM) sensor). According to another embodiment, the sensor module may further include, e.g., at least one of a gesture sensor, a gyro sensor, an atmospheric pressure sensor, a magnetic sensor, an acceleration sensor, a grip sensor, a color sensor, an infrared (IR) sensor, a temperature sensor, a humidity sensor, or an illuminance sensor. According to an embodiment, the sensor module may be disposed in the first housing 2201 and/or the second housing 2202. For example, at least a portion of the sensor module may be positioned in the first housing 2201, and another portion thereof may be positioned in the second housing 2202.

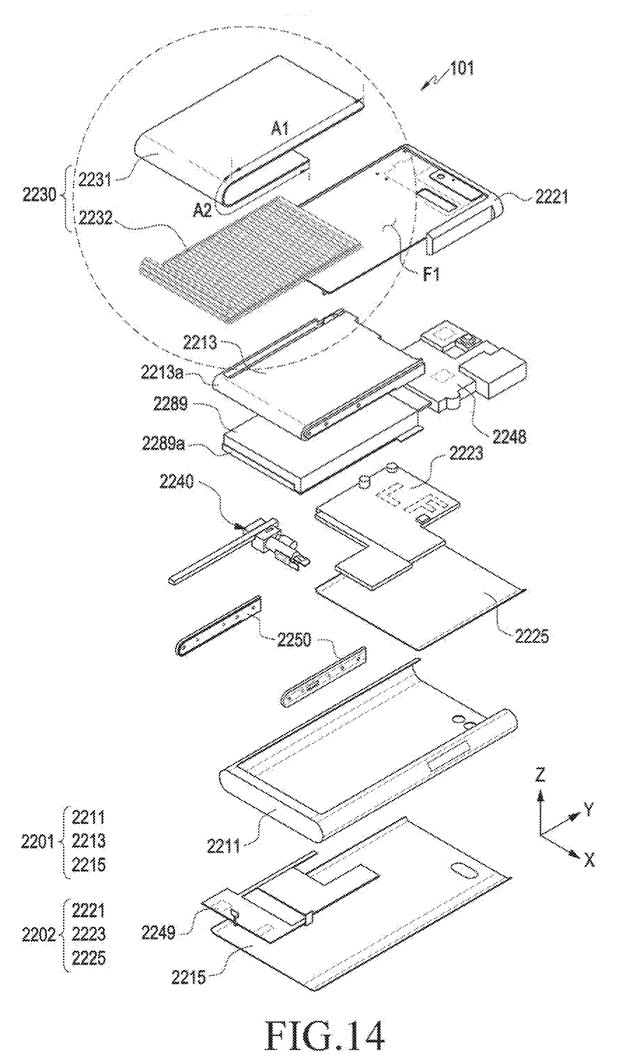

FIG. 14 is an exploded perspective view illustrating an electronic device 101 according to an embodiment of the disclosure.

Referring to FIGS. 12 to 14, according to an embodiment, the first cover member 2211 may accommodate at least a portion of the frame 2213 and accommodate a component (e.g., battery 2289) positioned in the frame 2213. According to an embodiment, the first cover member 2211 may be formed to surround at least a portion of the second housing 2202. According to an embodiment, the first cover member 2211 may protect the components (e.g., the second circuit board 2249 and the frame 2213) positioned in the first housing 2201 from external impact. According to an embodiment, the second circuit board 2249 receiving the electronic component (e.g., the processor 120 and/or the memory 130 of FIG. 1) may be connected to the first cover member 2211.

According to an embodiment, the frame 2213 may be connected to the first cover member 2211. For example, the frame 2213 may be connected to the first cover member 2211. The second housing 2202 is movable relative to the first cover member 2211 and/or the frame 2213. According to an embodiment, the frame 2213 may accommodate the battery 2289. For example, the frame 2213 may include a recess for receiving the battery 2289. The frame 2213 may be connected to the battery cover 2289a and, together with the battery cover 2289a, may surround at least a portion of the battery 2289. According to an embodiment, the frame 2213 may include a curved portion 2213a facing the display assembly 2230.

According to an embodiment, the first rear plate 2215 may substantially form at least a portion of the exterior of the first housing 2201 or the electronic device 101. For example, the first rear plate 2215 may be coupled to the outer surface of the first cover member 2211. According to an embodiment, the first rear plate 2215 may provide a decorative effect on the exterior of the electronic device 101. The first rear plate 2215 may be formed of at least one of metal, glass, synthetic resin, or ceramic.

According to an embodiment, the second housing 2202 may include a second cover member 2221, a rear cover 2223, and a second rear plate 2225.

According to an embodiment, the second cover member 2221 may be connected to the first housing 2201 through the guide rail 2250 and, while being guided by the guide rail 2250, reciprocate linearly in one direction (e.g., the direction of arrow ① in FIG. 3).

According to an embodiment, the second cover member 2221 may support at least a portion of the display 2203. For example, the second cover member 2221 may include a first surface F1. The first display area A1 of the display 2203 may be substantially positioned on the first surface F1 to maintain a flat panel shape. According to an embodiment, the second cover member 2221 may be formed of a metal material and/or a non-metal (e.g., polymer) material. According to an embodiment, the first circuit board 2248 accommodating the electronic component (e.g., the processor 120 and/or the memory 130 of FIG. 1) may be connected to the second cover member 2221. According to an embodiment, the second cover member 2221 may protect the components (e.g., the first circuit board 2248 and the rear cover 2233) positioned in the second housing 2202 from external impact.

According to an embodiment, the rear cover 2223 may protect a component (e.g., the first circuit board 2248) positioned on the second cover member 2221. For example, the rear cover 2223 may be connected to the second cover member 2221 and may be formed to surround at least a portion of the first circuit board 2248. According to an embodiment, the rear cover 2223 may include an antenna pattern for communicating with an external electronic device. For example, the rear cover 2223 may include a laser direct structuring (LDS) antenna.

According to an embodiment, the second rear plate 2225 may substantially form at least a portion of the exterior of the second housing 2202 or the electronic device 101. For example, the second rear plate 2225 may be coupled to the outer surface of the second cover member 2221. According to an embodiment, the second rear plate 2225 may provide a decorative effect on the exterior of the electronic device 101. The second rear plate 2225 may be formed of at least one of metal, glass, synthetic resin, or ceramic.

According to an embodiment, the display assembly 2230 may include a display 2231 (e.g., the display 2203 of FIGS. 12 and/or 13) and a multi-bar structure 2232 supporting the same. According to an embodiment, the display 2231 may be referred to as a flexible display, a foldable display, and/or a rollable display.

According to an embodiment, the first display area A1 of the display 2231 may be supported by a rigid body, and the second display area A2 may be supported by a bendable structure. For example, the first display area A1 may be supported by the first surface F1 of the second cover member 2221 or a plate (not shown). The second display area A2 may be supported by the multi-bar structure 2232.

According to an embodiment, the multi-bar structure 2232 may be connected to or attached to at least a portion (e.g., the second display area A2) of the display 2231. According to an embodiment, as the second housing 2202 slides, the multi-bar structure 2232 may move with respect to the first housing 2201. In the slide-in state of the electronic device 101 (e.g., FIG. 2), the multi-bar structure 2232 may be mostly received in the first housing 2201 and may be positioned between the first cover member 2211 and the second cover member 2221. According to an embodiment, at least a portion of the multi-bar structure 2232 may move corresponding to the curved surface 2213a positioned at the edge of the frame 2213. According to an embodiment, the multi-bar structure 2232 may be referred to as a display supporting member or supporting structure and may be in the form of one elastic plate.

According to an embodiment, the driving structure 2240 may move the second housing 2202 relative to the first housing 2201. The driving structure 2240 may include a motor configured to generate a driving force for sliding the second housing 2202 with respect to the first housing 2201. For example, a driving structure 2240 may include a pinion gear connected to the motor and a rack gear configured to engage with the pinion gear.

According to an embodiment, the motor may be controlled by a processor (e.g., the processor 120 of FIG. 1). For example, the processor (e.g., the processor 120 of FIG. 1) may include a motor driver driving circuit and transmit a signal for controlling a speed and/or torque of the motor to the motor.

According to an embodiment, the second housing 2202 may accommodate the first circuit board 2248 (e.g., a main board). According to an embodiment, the processor, memory, and/or interface may be mounted on the first circuit board 2248. The processor may include one or more of, e.g., a central processing unit, an application processor, a graphic processing device, an image signal processor, a sensor hub processor, or a communication processor.

According to various embodiments, the first circuit board 2248 may include a flexible printed circuit board type radio frequency cable (FRC). The first circuit board 2248 may be disposed on at least a portion of the second cover member 2221 and may be electrically connected to the antenna module and the communication module.

According to an embodiment, the electronic device 101 may include a second circuit board 2249 (e.g., a sub circuit board) spaced apart from the first circuit board 2248 (e.g., a main circuit board) in the first housing 2201. The second circuit board 2249 may be electrically connected to the first circuit board 2248 through a connection flexible board. The second circuit board 2249 may be electrically connected with electric components disposed in an end area of the electronic device 101, such as the battery 2289 or a speaker and/or a sim socket, and may transfer signals and power.

According to an embodiment, the second circuit board 2249 may receive a wireless charging antenna (e.g., a coil) or be connected to the wireless charging antenna. For example, the battery 2289 may receive power from an external electronic device through the wireless charging antenna. As another example, the battery 2289 may transfer power to the external electronic device by the wireless charging antenna.

According to an embodiment, the guide rail 2250 may guide the movement of the multi-bar structure 2232. According to an embodiment, the guide rail 2250 may be connected to the first housing 2201. For example, the guide rail 2250 may be connected to the first cover member 2211 and/or the frame 2213.

According to an embodiment, a guide rail 2250 may provide a force to a multi-bar structure 2232 based on the driving of the motor. The multi-bar structure 2232 that has received the force may move along the guide rail 2250, and a second housing 2202 may slide and move to extend with respect to a first housing 2201.

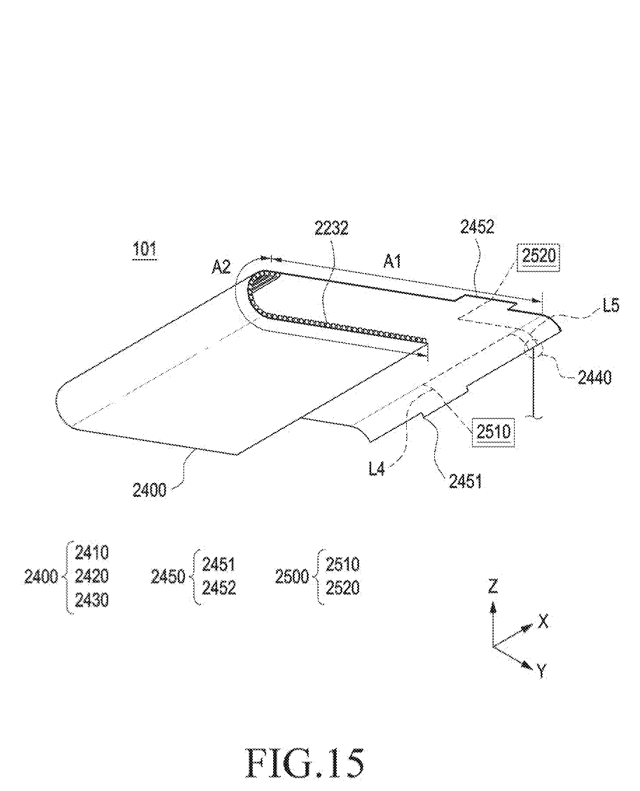

FIG. 15 is a perspective view illustrating a portion of an electronic device and a digitizer 2400 according to an embodiment of the disclosure.

The descriptions of the components (the first conductive layer 410, the second conductive layer 420, the connecting portion 430, the connector 440, and the electronic module 500) described with reference to FIGS. 4 to 6 may be equally applied to the components having the same names (the first conductive layer 2410, the second conductive layer 2420, the connecting portion 2430, the connector 2440, and the electronic module 2500) illustrated in FIG. 15, to the extent that they are not inconsistent with each other.

Referring to FIG. 15, a digitizer 2400 according to an embodiment of the disclosure may be referred to as a flexible digitizer or a rollable digitizer formed of a flexible material. The digitizer 2400 may be disposed beneath the display 2231. The signal lines L4 and L5 may extend along the display 2231. The digitizer 2400 may include a first portion A1 and a second portion A2 bent from the first portion A1.

The first portion A1 of the digitizer 2400 according to an embodiment of the disclosure may be a region corresponding to the first region A1 of the display 2231. The second portion A2 of the digitizer 2400 may be a region corresponding to the second region A2 of the display 2231.

The first portion A1 of the digitizer 2400 according to an embodiment of the disclosure may be moved together with the first region A1 of the display 2231. The second portion A2 of the digitizer 2400 may be moved together with the second region A2 of the display 2231. The second portion A2 of the digitizer 2400 may be bent together with the second region A2 of the display 2231.

Referring to FIG. 15, the plurality of electronic modules 2500 according to an embodiment of the disclosure may be connected to a connector 2440 through signal lines L4 and L5 disposed in the digitizer 2400.

According to an embodiment of the disclosure, the signal lines L4 and L5 may be disposed in the first portion A1 of the digitizer 2400. The signal lines L4 and L5 may include a fourth signal line L4 connecting the connector 2440 and a first electronic module 2510. The signal lines L4 and L5 may include a fifth signal line L5 connecting the connector 2440 and a second electronic module 2520.

According to an embodiment of the disclosure, the electronic modules 2500 may be located around an edge of the digitizer 2400. The electronic modules 1500 may be disposed around an edge of the first portion A1 of the digitizer 1400.

The digitizer 2400 according to an embodiment of the disclosure may include mounting portions 2450 formed at an outer edge of the first conductive layer 2410 and/or the second conductive layer 2420. The plurality of electronic modules 2500 may be disposed on the mounting portions 2450.

The electronic modules 2500 according to an embodiment of the disclosure may include a first electronic module 2510 disposed on the first mounting portion 2451. The electronic modules 2500 may include a second electronic module 2520 disposed on the second mounting portion 2452.

The fourth signal line L4 according to an embodiment of the disclosure may include a plurality of traces disposed in the first conductive layer 2410 and the second conductive layer 2420. The fourth signal line L4 may include a connecting portion (e.g., the connecting portion 430 of FIGS. 5 and 6) electrically connecting the first conductive layer 2410 and the second conductive layer 2420. The traces constituting the fourth signal line L4 may be electrically connected through the connecting portion (e.g., the connecting portion 430 of FIGS. 5 and 6).

The fifth signal line L5 according to an embodiment of the disclosure may include a plurality of traces disposed in the first conductive layer 2410 and the second conductive layer 2420. The fifth signal line L5 may include a connecting portion (e.g., the connecting portion 430 of FIGS. 5 and 6) electrically connecting the first conductive layer 2410 and the second conductive layer 2420. The traces constituting the fifth signal line L5 may be electrically connected through the connecting portion (e.g., the connecting portion 430 of FIGS. 5 and 6).

The digitizers 400, 1400, 2400, and 3400 according to an embodiment of the disclosure may include at least one adhesive layer (not illustrated). The adhesive layers may include an adhesive member (not illustrated). The adhesive layers may be disposed between the conductive layers 410, 420, 1410, 1420, 2410, and 2420, the shielding layer 460, and the ground layers 470 and 3470 to adhere two adjacent layers to each other. The adhesive layers may include an insulating member (not illustrated). The adhesive layers may block electrical conduction between two adjacent layers.

As the electronic device is downsized for reasons such as enhancing user convenience, interference may occur between components (e.g., a display, a camera, a cable, or the like) constituting the electronic device. Accordingly, much research is being conducted to minimize interference between the components of the electronic device by minimizing the number of components of the electronic device or by enhancing an arrangement structure between the components.

A problem to be solved by the disclosure may be to minimize the number of components of an electronic device including a digitizer.

A problem to be solved by the disclosure may be to minimize interference between components of an electronic device including a digitizer.

A problem to be solved by the disclosure may be to ground a signal line added to a digitizer without increasing a thickness of the digitizer.

The problems to be solved by the disclosure are not limited to the above-mentioned problems, and may be variously extended without departing from the spirit and scope of the disclosure.

An electronic device according to various embodiments of the disclosure may minimize the number of components of the electronic device by disposing a signal line connected to an electronic module in a digitizer.

An electronic device according to various embodiments of the disclosure may minimize interference between components that move relative to each other by disposing a signal line connected to an electronic module movable with respect to a portion of the electronic device in a digitizer.

An electronic device according to various embodiments of the disclosure may provide a grounding structure that does not impair performance of a digitizer by connecting a ground layer and a signal line connected to an electronic module through an outer edge portion of the digitizer.

The effects that may be obtained in the disclosure are not limited to the effects mentioned above, and other effects not mentioned is clearly understood by those skilled in the art to which the disclosure belongs from the aforementioned description.

An electronic device according to an embodiment of the disclosure may include an electronic module 500, 1500, or 2500 disposed around the display panel 330 or 2203.

An electronic device according to an embodiment of the disclosure may include a processor 120 configured to control the electronic module 500, 1500, or 2500.

An electronic device according to an embodiment of the disclosure may include a digitizer 400, 1400, 2400, or 3400 disposed beneath the display panel 330 or 2203.

The digitizer 400, 1400, 2400, or 3400 according to an embodiment of the disclosure may include a first conductive layer 410, 1410, or 2410 on which a plurality of first coils 411 are disposed.

The digitizer 400, 1400, 2400, or 3400 according to an embodiment of the disclosure may include a second conductive layer 420, 1420, or 2420 on which a plurality of second coils 421 are disposed, the first conductive layer 410, 1410, or 2410 being disposed between the second conductive layer 420, 1420, or 2420 and the display panel 330 or 2203.

The digitizer 400, 1400, 2400, or 3400 according to an embodiment of the disclosure may include a signal line L, L1, L2, L3, L4, or L5 disposed in at least one of the first conductive layer 410, 1410, or 2410 and the second conductive layer 420, 1420, or 2420, the signal line L, L1, L2, L3, L4, or L5 electrically connecting the electronic module 500, 1500, or 2500 and the processor 120.

According to an embodiment of the disclosure, the signal line L, L2, or L3 may include a second trace 422, 1423, or 1425 disposed in the second conductive layer 420 or 1420.

According to an embodiment of the disclosure, the signal line L, L2, or L3 may include a first trace 412, 1412, or 1414 disposed in the first conductive layer 410 or 1410 and extending in a direction intersecting the second trace 422, 1423, or 1425.

According to an embodiment of the disclosure, the signal line L, L2, or L3 may include a first via 431 connecting the first trace 412, 1412, or 1414 and the second trace 422, 1423, or 1425.

According to an embodiment of the disclosure, an outer edge of the digitizer 400 or 1400 may include a first edge and a second edge that extend along an outer edge of the display panel 330 and that intersect with each other.

According to an embodiment of the disclosure, the first trace 412, 1412, or 1414 may extend along the first edge.

According to an embodiment of the disclosure, the second trace 422, 1423, or 1425 may extend along the second edge.

According to an embodiment of the disclosure, the signal line L may include: a third trace 423 disposed in the second conductive layer 420, extending along the second trace 422, and connected to the electronic module 500.

According to an embodiment of the disclosure, the signal line L may include a second via 432 connecting the first trace 412 and the third trace 423.

According to an embodiment of the disclosure, the signal line L2 may include a third trace 1413 disposed in the first conductive layer 1410, extending along the first trace 1412, and electrically connected to the electronic module 1520.

According to an embodiment of the disclosure, the signal line L2 may include a second via connecting the second trace 1423 and the third trace 1413.

According to an embodiment of the disclosure, the digitizer 400, 1400, or 2400 may include a connector 440, 1440, or 2440 to which the plurality of first coils 411, the plurality of second coils 421, and the signal line L, L1, L2, L3, L4, or L5 are connected.

According to an embodiment of the disclosure, the electronic module 500 and the connector 440 may be positioned opposite to each other with respect to the display panel 330.

According to an embodiment of the disclosure, the electronic module 500 and the connector 440 may be spaced apart from each other in the length direction of the first edge.

According to an embodiment of the disclosure, the electronic module 500 and the connector 440 may be spaced apart from each other in the length direction of the second edge.

According to an embodiment of the disclosure, the digitizer 400 may include a shielding layer 460 disposed beneath the second conductive layer 420.

According to an embodiment of the disclosure, the digitizer 400 may include a ground layer 470 disposed beneath the shielding layer 460.

According to an embodiment of the disclosure, the ground layer 470 may include a connecting portion 471 connected to the second conductive layer 420 through the shielding layer 460.

According to an embodiment of the disclosure, the connecting portion 471 may be located around an outer edge of the shielding layer 460.

According to an embodiment of the disclosure, the connecting portion 471 may contact an outer edge of the second conductive layer 420.

According to an embodiment of the disclosure, a frequency of a current flowing in the signal line L, L1, L2, L3, L4, or L5 may be greater than a frequency of a current flowing in the first coil 411 and the second coil 421.

According to an embodiment of the disclosure, the shielding layer 460 may be disposed between the second conductive layer 420 and the ground layer 470.

According to an embodiment of the disclosure, the shielding layer 460 may include magnetic metal powder (MMP).

According to an embodiment of the disclosure, the digitizer 1400 or 2400 may include a mounting portion 1450 or 2450 formed on one of the first conductive layer 1410 or 2410 and the second conductive layer 1420 or 2420.

According to an embodiment of the disclosure, the electronic module 1500 or 2500 may be disposed on the mounting portion 1450 or 2450.

According to an embodiment of the disclosure, the mounting portion 1450 or 2450 may extend from an outer edge of one of the first conductive layer 1410 or 2410 and the second conductive layer 1420 or 2420.

According to an embodiment of the disclosure, the digitizer 2400 may include a first portion A1 on which the signal line L4 or L5 is disposed, wherein the electronic module 2500 is disposed around an outer edge of the first portion A1.

According to an embodiment of the disclosure, the digitizer 2400 may include a second portion A2 bent from the first portion A1 toward an inside of the electronic device and disposed inside the electronic device.

According to an embodiment of the disclosure, the electronic device may include a plurality of electronic modules 1510, 1520, and 1530, or 2510 and 2520 disposed around an outer edge of the display panel 330 or 2203.

According to an embodiment of the disclosure, the electronic device may include a processor 120 configured to control the plurality of electronic modules 1510, 1520, and 1530, or 2510 and 2520.

According to an embodiment of the disclosure, the digitizer 1400 or 2400 may include a plurality of signal lines L1, L2, and L3, or L4 and L5 electrically connecting the plurality of electronic modules 1510, 1520, and 1530, or 2510 and 2520 and the processor 120.

According to an embodiment of the disclosure, the plurality of signal lines L1, L2, and L3, or L4 and L5 may be disposed in at least one of the first conductive layer 1410 or 2410 and the second conductive layer 1420 or 2420.

The drawings referenced above include X, Y, and Z coordinate axes having the same orientations. The coordinate axes included in each drawing are for convenience of description, and the directions of each axis (X-axis, Y-axis, and Z-axis) do not have directionality such as forward/backward direction, up-down direction, and left-right direction, and the directions of each axis may be understood as +X, +Y, and +Z directions, and directions opposite thereto may be understood as −X, −Y, and −Z directions.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device, comprising:
a display panel;
an electronic module disposed around the display panel;
a processor configured to control the electronic module; and
a digitizer disposed beneath the display panel,
wherein the digitizer comprises:
a first conductive layer on which a plurality of first coils are disposed,
a second conductive layer on which a plurality of second coils are disposed, wherein the first conductive layer is disposed between the second conductive layer and the display panel, and
a signal line disposed in at least one of the first conductive layer and the second conductive layer, the signal line electrically connecting the electronic module and the processor.

2. The electronic device of claim 1, wherein the signal line comprises:
a first trace disposed in the first conductive layer;
a second trace disposed in the second conductive layer and extending in a direction intersecting the first trace; and
a first via connecting the first trace and the second trace.

3. The electronic device of claim 2,
wherein an outer edge of the digitizer comprises a first edge and a second edge that extend along an outer edge of the display panel and that intersect with each other,
wherein the first trace extends along the first edge, and
wherein the second trace extends along the second edge.

4. The electronic device of claim 2, wherein the signal line further comprises:
a third trace disposed in the second conductive layer and extending along the second trace and connected to the electronic module; and
a second via connecting the first trace and the third trace.

5. The electronic device of claim 2, wherein the signal line further comprises:
a third trace disposed in the first conductive layer and extending along the first trace and electrically connected to the electronic module; and
a second via connecting the second trace and the third trace.

6. The electronic device of claim 1, wherein the digitizer comprises:
a connector to which the plurality of first coils, the plurality of second coils, and the signal line are connected.

7. The electronic device of claim 6, wherein the electronic module and the connector are positioned opposite to each other with respect to the display panel.

8. The electronic device of claim 6,
wherein an outer edge of the digitizer comprises a first edge and a second edge which extend along an outer edge of the display panel and which intersect with each other, and
wherein the electronic module and the connector are spaced apart from each other in a longitudinal direction of the first edge and are spaced apart from each other in a longitudinal direction of the second edge.

9. The electronic device of claim 1, wherein the digitizer comprises:
a shielding layer disposed beneath the second conductive layer; and
a ground layer disposed beneath the shielding layer, the ground layer including a connecting portion which is connected to the second conductive layer through the shielding layer.

10. The electronic device of claim 9, wherein the connecting portion is located around an outer edge of the shielding layer and contacts an outer edge of the second conductive layer.

11. The electronic device of claim 1, wherein a frequency of a current flowing in the signal line is greater than a frequency of a current flowing in a first coil of the plurality of first coils and a second coil of the plurality of second coils.

12. The electronic device of claim 9, wherein the shielding layer is disposed between the second conductive layer and the ground layer, the shielding layer comprising magnetic metal powder (MMP).

13. The electronic device of claim 1,
wherein the digitizer comprises a mounting portion formed on one of the first conductive layer and the second conductive layer, and
wherein the electronic module is disposed on the mounting portion.

14. The electronic device of claim 13, wherein the mounting portion extends from an outer edge of one of the first conductive layer and the second conductive layer.

15. The electronic device of claim 1, wherein the digitizer comprises:
a first portion on which the signal line is disposed, wherein the electronic module is disposed around an outer edge of the first portion; and
a second portion bent from the first portion toward an inside of the electronic device and disposed inside the electronic device.

16. The electronic device of claim 3, wherein the signal line further comprises:
a third trace disposed in the second conductive layer and extending along the second trace and connected to the electronic module; and
a second via connecting the first trace and the third trace.

17. The electronic device of claim 3, wherein the signal line further comprises:
a third trace disposed in the first conductive layer and extending along the first trace and electrically connected to the electronic module; and
a second via connecting the second trace and the third trace.

18. The electronic device of claim 2, wherein the digitizer comprises:
a connector to which the plurality of first coils, the plurality of second coils, and the signal line are connected.

19. The electronic device of claim 7,
wherein an outer edge of the digitizer comprises a first edge and a second edge which extend along an outer edge of the display panel and which intersect with each other, and
wherein the electronic module and the connector are spaced apart from each other in a longitudinal direction of the first edge and are spaced apart from each other in a longitudinal direction of the second edge.

20. The electronic device of claim 2, wherein the digitizer comprises:
a shielding layer disposed beneath the second conductive layer; and
a ground layer disposed beneath the shielding layer, the ground layer including a connecting portion which is connected to the second conductive layer through the shielding layer.
